(19) United States
(12) Patent Application Publication
(10) Pub. No.: US 2006/0033515 A1
(43) Pub. Date: Feb. 16, 2006

(54) Test fixture with movable pin contacts

(75) Inventor: Belgacem Haba, Saratoga, CA (US)

Correspondence Address: TESSERA;LERNER DAVID et al., 600 SOUTH AVENUE WEST, WESTFIELD, NJ, 07090, US

(73) Assignee: Tessera, Inc., San Jose, CA (US)

(21) Appl. No.: 11/202,498

(22) Filed: Aug. 12, 2005

Related U.S. Application Data
(60) Provisional application No. 60/601,565, filed on Aug. 13, 2004.

(51) Int. Cl. G01R 31/02

(52) U.S. Cl. 324/754

(57) ABSTRACT

A fixture for testing microelectronic elements such as semiconductor chips. The test fixture includes a body and a flexible dielectric substrate supported above the body by support elements. Conductive posts are connected to the body with support elements. The conductive posts project from the surface of the dielectric element. The conductive posts interact with pads on a semiconductor chip to be tested. The conductive posts are displaced toward the body, deforming the dielectric substrate, when necessary to engage uneven pads on a semiconductor chip. When a semiconductor chip is positioned over the test fixture, the conductive posts automatically engage the various pads on the chip at their respective heights.

### CROSS-REFERENCE TO RELATED APPLICATIONS

The present application claims the benefit of the filing date of U.S. Provisional Patent Application No. 60/601,565, filed Aug. 13, 2004, the disclosure of which is hereby incorporated by reference herein.

### BACKGROUND OF THE INVENTION

The present invention relates to methods and apparatus for testing microelectronic elements such as packaged or unpackaged semiconductor chips.

Microelectronic elements such as semiconductor chips are commonly provided in packages which incorporate the chip itself, together with a package substrate such as a dielectric element having terminal structures mounted thereon. The terminal structures typically include flat metallic pads, with or without masses of bonding material thereon. In one common form of chip package, known as a ball grid array or “BGA” package, the terminal structures include pads on the dielectric substrate, with solder balls affixed to the pads. Such a package can be mounted to a circuit board by reflowing the solder balls, so that the solder balls bond the pads of the package to corresponding pads on the circuit board.

A land grid array or “LGA” package also includes an array of pads on the dielectric substrate, each such pad having a relatively thin layer of solder, referred to as a solder land thereon. A land grid array package can be mounted to the circuit board by reflowing the solder lands. In a “flip-chip” arrangement, a bare or unpackaged chip can be mounted to a circuit board by soldering the contacts of the chip itself to the contact pads of the circuit board. In this arrangement, the contacts of the bare chip, with or without solder thereon, serve as the terminal structures.

It is highly desirable to test a packaged or unpackaged chip before mounting the same to a circuit board. As disclosed in co-pending, commonly assigned U.S. Provisional Patent Application Nos. 60/533,210; 60/533,393; and 60/533,437, the disclosures of which are hereby incorporated by reference herein, difficulties can arise in testing conventional packaged or unpackaged microelectronic elements. For example, where the terminal structures are nominally coplanar with one another, it should be possible to engage all of the terminal structures with contact pads of a test fixture which are also coplanar with one another. However, the terminal structures, the contact pads or both may be out of plane, so that it is difficult to engage all of the terminal structures with all of the contact pads. Oxides or other contaminants on the surfaces of the terminal structures also can impede engagement with the test fixture.

One solution to these difficulties, discussed in greater detail in certain aspects of the aforementioned co-pending applications, is to provide a chip package which includes a flexible dielectric element supported above the surface of the chip or other microelectronic element by a set of support elements. The terminal structures of the package include electrically conductive posts projecting from the dielectric element. These posts are offset from the support structures. Such a package may be engaged with a test fixture so as to forcibly engage the tips of the posts, remote from the dielectric element, with contact pads of the test fixture. During such engagement, the dielectric element can deform in the regions between the support elements, thus allowing the posts to move toward the microelectronic element. This action compensates for non-planarity of the post tips or non-planarity of the contact pads on the test fixture. Deformation of the substrate also allows the posts to tilt, so that the tips of the posts tend to wipe across the contact pads of the test fixture. The wiping action helps to provide reliable contact despite the presence of contaminants.

### SUMMARY OF THE INVENTION

A test fixture according to one aspect of the present invention includes a body and a flexible dielectric substrate, supported above a surface of the body by support elements. Electrically conductive posts project from the surface of the dielectric element. Such a test fixture can be engaged with a microelectronic element having terminal structures such as flat pads or pads bearing solder balls or solder lands. The support elements, dielectric substrate and posts of the test fixture can include features similar to those incorporated in packages according to the preferred embodiments of the aforementioned co-pending applications.

A further aspect of the invention provides methods of testing microelectronic elements.

### BRIEF DESCRIPTION OF THE DRAWINGS

FIG. 1 is a cross-sectional view of a test fixture according to one embodiment of the present invention.

FIG. 2 is a cross-sectional view of the test fixture shown in FIG. 1 interacting with a microelectronic element.

### DETAILED DESCRIPTION

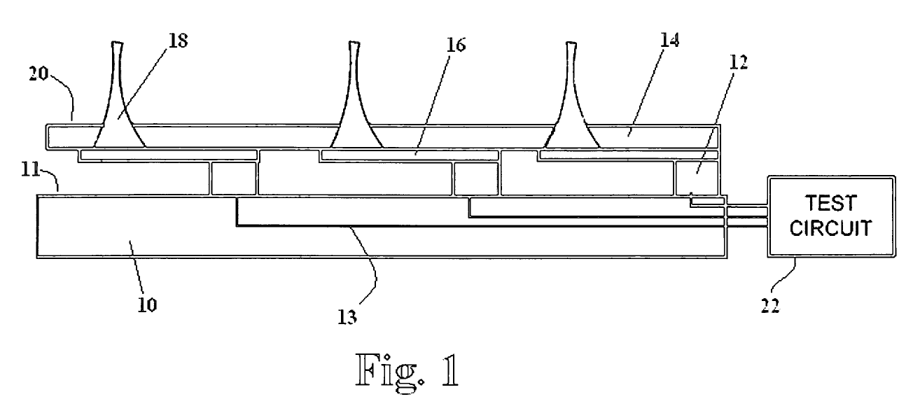

A test fixture in accordance with one embodiment of the present invention is schematically shown in FIG. 1. The test fixture includes a fixture body 10. Body 10 may be formed of any material capable of mechanically supporting the other elements discussed below. In the particular embodiment shown, body 10 is a dielectric element such as a circuit board having electrical conductors 13 thereon. A plurality of electrically conductive support elements 12 extend upwardly from the surface 11 of the fixture body. A flexible dielectric substrate 14 is supported above face 11 of the fixture body by the support elements 12. Substrate 14 bears electrically conductive traces 16. The traces 16 are referred to herein as being “on” substrate 14, and conductors 13 are referred to herein as being “on” body 10. However, this should not be taken as requiring that the traces or conductors be disposed on a surface of the substrate or body; traces “on” a substrate or body may be on a surface or within the interior of the substrate or body. Also, the substrate and body may include one layer or more than one layer of traces.

Electrically conductive posts 18 project in a generally vertical direction, also referred to herein as the projection direction (towards the top of the drawing in FIG. 1) beyond the surface 20 of substrate 14 facing away from body 10. Directions such as “upwardly” or “vertical” stated herein are given in the frame of reference of the components, and need not correspond to the normal gravitational frame of reference. Posts 18 are electrically connected to support elements 12 by traces 16. Support elements 12, in turn, are connected by the conductors 13 of the body to a test circuit 22 adapted to apply power, signals or both to a microelectronic element to be tested and/or to receive power, signals or both from the microelectronic element.

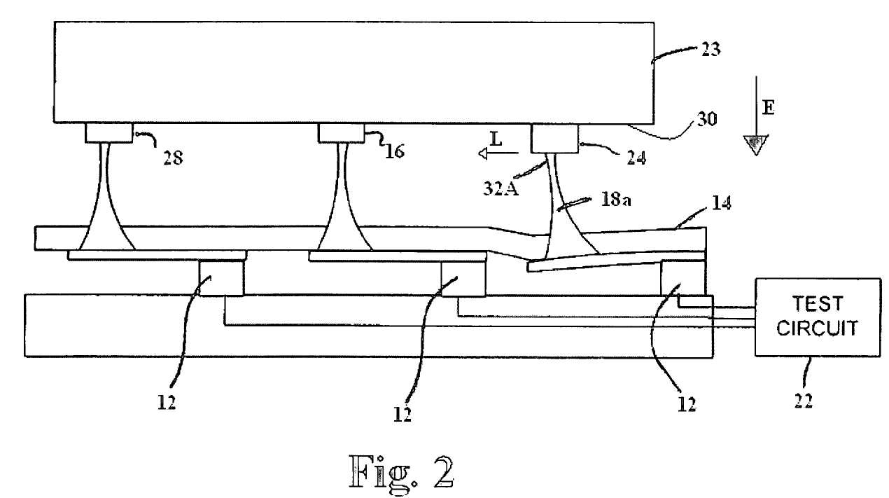

As shown in FIG. 2, a microelectronic element 23 such as a packaged or unpackaged semiconductor chip having terminal structures 24, 26 and 28 exposed at a surface of the microelectronic element is engaged with the test fixture by moving the microelectronic element with a component of motion toward the test fixture, in an engagement direction E (towards the bottom of the drawing in FIG. 2). The terminal structures are nominally coplanar with one another, but due to manufacturing tolerances, are actually out of plane; in particular, terminal structure 24 is not coplanar with terminal structures 26 and 28. As the microelectronic element 23 is moved toward the test fixture and toward substrate 14, the substrate deforms as schematically shown in FIG. 2, in the regions between support elements 12, so that the posts 18 are displaced downwardly toward body 10. The deformation of the substrate is shown only in the vicinity of one post 18a, but in practice, such deformation typically occurs in the vicinity of all of the posts, so that all of the posts move downwardly to some extent. However, the extent of such downward motion need not be equal. In particular, post 18a, engaged with out-of-plane, projecting terminal structure 24, has moved downwardly to a greater degree than the other posts. This allows the posts to engage the terminal structures reliably, even where the terminal structures, the posts or both are out of plane.

As also shown in FIG. 2, deformation of the flexible substrate causes the posts to tilt. Thus, the tip 32a of post 18a has moved in a lateral direction L, transverse to the projection direction of the posts. Such lateral movement promotes wiping of the post tips on the terminal structure, which in turn, promotes reliable contact between the post tips and the terminal structures.

Engagement of the terminal structures with the posts electrically connects the test circuit 22 to the microelectronic element 23. The test circuit actuates the microelectronic element. The test operation may or may not include an operation in which the test circuit determines whether the microelectronic element is operating reliably; the terms “test” and “testing” as used herein also include the operation commonly referred to as “burn-in”, in which a microelectronic element is operated for a limited time, with or without determining whether it is operating reliably during such operation. After testing, the microelectronic device 23 is disengaged from the test fixture, and the same sequence of operations is repeated using another microelectronic device.

The test fixture may incorporate posts, support elements and related structures similar to those described in the aforementioned co-pending, commonly assigned patent applications. It is not essential that the support elements 12 be electrically conductive. For example, the test circuit may be connected to the posts by way of traces on the dielectric substrate 14. Where such traces, or other connections to the test circuit are employed, the support elements need not be electrically conductive, and the body need not incorporate conductive elements.

The disclosure of U.S. Pat. No. 6,086,386 is also incorporated by reference herein.

As these and other variations and combinations of the features discussed above can be utilized without departing from the present invention as defined by the claims, the foregoing description of the preferred embodiments should be taken by way of illustration rather than by way of limitation of the invention as defined by the claims.

1. A test fixture for testing microelectronic elements, said test fixture comprising:
a body having a first surface;
a flexible substrate spaced from and overlying said first surface of said body;
a plurality of electrically conductive posts extending from said flexible substrate and projecting away from said body; and
a plurality of support elements disposed between said body and said substrate and supporting said flexible substrate over said body, at least some of said conductive posts being offset from said support elements,
said posts and substrate being constructed and arranged so that a microelectronic element to be tested can be engaged with said posts with said posts bearing on terminal structures of the microelectronic element.

2. The fixture of claim 1 further comprising a test circuit electrically connected to at least some of said posts so that when a microelectronic element is engaged with said posts, said test circuit is electrically connected to the microelectronic element through at said least some of said posts and the terminal structures of the microelectronic element engaged therewith.

3. The fixture of claim 2 wherein said test circuit is operable to interchange signals at a frequency above about 300 MHz with the microelectronic element.

4. The fixture of claim 1 further comprising electrically conductive traces on said flexible substrate.

5. The fixture of claim 1 wherein at least some of said support elements are electrically conductive.

6. The fixture of claim 5 wherein at least some of said posts are connected to conductive support elements immediately adjacent to such posts.

7. The fixture of claim 5, further comprising conductive traces on said flexible substrate, wherein said conductive traces electrically interconnect at least some of said conductive posts with at least some of said conductive support elements.

8. The fixture of claim 1, wherein said posts are disposed in a grid array on said substrate.

9. The fixture of claim 1, wherein said flexible substrate comprises a dielectric sheet.

10. The fixture of claim 1, further comprising a compliant material disposed between said flexible substrate and said microelectronic element.

11. The fixture of claim 1, wherein said conductive posts are elongated and have tips remote from said flexible dielectric substrate, said tips being adapted to engage terminal structures of the microelectronic element.

12. A method of testing a microelectronic element having terminal structures comprising:
(a) engaging the terminal structures of the microelectronic element with posts projecting from a flexible dielectric substrate while the substrate is supported above a fixture body by a plurality of support elements offset from said posts so that at least some portions of the dielectric substrate deform; and
(b) testing the microelectronic element by transmitting signals, power or both to or from the microelectronic element through the engaged posts and terminal structures.

13. The method as claimed in claim 12 further comprising disengaging the terminal structures from the posts.

14. The method as claimed in claim 14 further comprising repeating the engaging, testing and disengaging steps using different microelectronic elements and the same posts, substrate and body.

15. The method as claimed in claim 12 wherein said terminal structures of said microelectronic element include solder masses.

16. The method as claimed in claim 12 wherein said terminal structures of said microelectronic element include a land grid array.

17. The method as claimed in claim 12 wherein said terminal structures of said microelectronic element include a ball grid array.

18. The method as claimed in claim 12 wherein said terminal structures are nominally coplanar with one another, and wherein deformation of said substrate at least partially compensates for deviation from coplanarity of said terminal structures.

19. The method as claimed in claim 12 wherein said posts project in a projection direction from said substrate and said engaging step includes moving said microelectronic element toward said substrate with a component of motion in a direction opposite to said projection direction.

20. The method as claimed in claim 19 wherein deformation of said substrate allows at least some of said posts to tilt during said engaging step so that tips of such posts move in lateral directions transverse to said projection direction and said tips wipe said terminal structures during said engaging step.
